(19) United States
(12) Patent Application Publication
(10) Pub. No.: US 2010/0018052 A1
(43) Pub. Date: Jan. 28, 2010

(54) Method of manufacturing printed circuit board for optical waveguide

(75) Inventors: Sang Hoon Kim, Gyungoi-do (KR); Han Seo Cho, Daejeon (KR); Jae Hyun Jung, Gyunggi-do (KR); Joon Sung Kim, Gyunggi-do (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/285,423

(22) Filed: Oct. 3, 2008

(30) Foreign Application Priority Data
Jul. 23, 2008 (KR) 10-2008-0071868

(51) Int. Cl. H05K 3/02

(52) U.S. Cl. 29/846

(57) ABSTRACT

Disclosed herein is a method of manufacturing a printed circuit board for an optical waveguide which includes electrical and optical layers for transmitting electrical and optical signals to the printed circuit board. The method includes forming a lower clad layer on a base substrate, layering or applying a core material on the lower clad layer, machining a trench in the core material to form a core layer having a core pattern, and forming an upper clad layer on the lower clad layer and the core layer. The method enables an optical waveguide to be manufactured using a simple apparatus and process without the use of an additional photo mask.

### CROSS-REFERENCE TO RELATED APPLICATIONS

This application claims the benefit of Korean Patent Application No. 10-2008-0071868, filed Jul. 23, 2008, entitled “A METHOD OF MANUFACTURING A PRINTED CIRCUIT BOARD FOR OPTICAL WAVEGUIDES”, which is hereby incorporated for reference in its entirety into this application

### BACKGROUND OF THE INVENTION

1. Field of the Invention

The present invention relates to a method of manufacturing a printed circuit board for an optical waveguide which includes electrical and optical layers for transmitting electrical and optical signals to the printed circuit board.

2. Description of the Related Art

In response to the speeding up of information and the development of large-volume data, technologies for improving transmission speed and transmission capacity have been required. However, in the case of the typical printed circuit board having electrical layers, there are limitations on the high-speed transmission of large-volume data due to limitations in the transmission speed (2.5 Gbps or less), crosstalk between electrical layers, limitation of packaging density, EMI (Electromagnetic Interference), and the like.

Accordingly, intensive research concerning a printed circuit board for an optical waveguide, which has a hybrid structure in which optical fiber/optical waveguide is embedded in the printed circuit board, thus laminating an optical layer and an electrical layer, is being actively carried out.

Typically, the optical layer is composed of a core layer, through which an optical signal is actually transmitted, and which is made of highly transparent polymer material and has a square cross section, and a clad part surrounding the core layer and having a lower index of refraction than the core layer, wherein the core layer having a square cross section is typically prepared using a photo-etching technology or a technology of changing an index of refraction of the core material by irradiation with ultraviolet laser.

In this regard, FIGS. 1 to 3 are cross-sectional views showing a first conventional method of manufacturing a printed circuit board for an optical waveguide using photo-etching. Referring to these drawings, the first conventional method is described below.

First, a lower clad layer 12 is formed on a base substrate 11, and a core material 13 is applied on the lower clad layer 12 (see FIG. 1).

The core material 13 is patterned using a photo-etching process and other similar processes, thus forming a core layer 15 (see FIG. 2).

At this point, the photo-etching process is conducted in a manner such that the core material 13 is exposed to ultraviolet light through a photo mask having a predetermined pattern, and an unexposed region of the core material 13 is dissolved using developing solution (e.g. acetone), thus forming the core layer 15.

Finally, an upper clad layer 16 is formed on the lower clad layer 12 including the core layer 15 formed thereon, thus finishing the manufacture of the printed circuit board for an optical waveguide (see FIG. 3).

FIGS. 4 to 6 are cross-sectional views showing a second conventional method of manufacturing a printed circuit board for an optical waveguide using irradiation of the core material by an ultraviolet laser to change an index of refraction of the core material. Referring to these drawings, the second conventional method is described below.

First, a lower clad layer 22 is formed on a base substrate 22, and a polymer layer 23 having a high index of refraction is applied on the lower clad layer 22 (see FIG. 4).

Subsequently, a region of the polymer layer 23 is irradiated with ultraviolet laser, except for a region of the polymer layer 23 corresponding to a core pattern, in order to change an index of refraction of the polymer layer 23 (see FIG. 5). As a result, the region of the polymer layer 23, which was irradiated with the ultraviolet laser, is changed in index of refraction, and thus serves as a side clad layer 25B whereas the other region of the polymer layer, which has not been irradiated with the ultraviolet laser, serves as a core layer 25A having a higher index of refraction than the side clad layer 25B.

Finally, an upper clad layer 106 is formed on the core layer 25A and the side clad layer 25B, thus finishing the manufacture of the printed circuit board 20 for an optical waveguide (see FIG. 6).

However, in the case of forming the core layer 15 using the photo-etching technology employed in the first conventional process, the photo mask is inevitably used. In particular, in order to reduce a roughness of a lateral surface of the core pattern and thus to reduce optical transmission loss, there is a problem in that expensive photo masks having a clean mask pattern must be used. In addition, in case that there is insufficient adhesive force between the core layer 15 and the lower clad layer 12 (in case that a roughness of an interface between the core layer 15 and the lower clad layer 12 is low) in the developing process, it is difficult to normally form a core wiring. In contrast, in case that the roughness of the interface is high, it is difficult to achieve mechanical/chemical surface treatment due to an increase in optical transmission loss.

Meanwhile, in the second conventional process of changing an index of refraction of core material using irradiation by ultraviolet laser and forming the core layer 25A, there is a problem in that the core material is limited to a specific material which is able to have its index of refraction be changed by irradiation with an ultraviolet laser. Furthermore, because it forms a core pattern in an indirect way such that indexes of refraction of an irradiated region and a non-irradiated region of core material are differentiated from each other by being irradiated with ultraviolet laser, the boundary between the irradiated region and the non-irradiated region is not always clear, thus making realization of an optical layer having a fine pattern difficult.

### SUMMARY OF THE INVENTION

Accordingly, the present invention has been made keeping in mind the above problems occurring in the prior art, and the present invention provides a method of manufacturing a printed circuit board for an optical waveguide which is capable of forming a core layer using a simple apparatus, and a process of etching core material by laser beam machining.

In one aspect, the present invention provides a method of manufacturing a printed circuit board for an optical waveguide, including: (A) forming a lower clad layer on a base substrate; (B) layering or applying a core material on the lower clad layer; (C) machining a trench in the core material to form a core layer having a core pattern; and (D) forming an upper clad layer on the lower clad layer and the core layer.

The base substrate may be a printed circuit board on which a circuit pattern is formed on one or both surfaces of an insulating layer.

In the method, (C) machining the trench includes: (C1) placing the base substrate, on which the lower clad layer and the core material are sequentially formed, on an X-Y movable table which is adjusted in a position; (C2) positioning the X-Y movable table such that an opening of an opening mask positioned over the X-Y movable table is aligned with a region of the core material at which the trench is to be formed; and (C3) machining the trench using a laser beam, thus forming the core layer having the core pattern.

The laser beam may be a CO₂ laser beam.

The opening of the opening mask may be a polygon opening having linear sides.

In (C3) machining the trench, the trench may be machined longitudinally by adjusting a position of the X-Y movable table.

In (C3) machining the trench, the core pattern may be formed to have a right-angled corner in order to transmit an optical signal in a direction deflected at a right angle.

After (D) forming the upper clad layer, the method may further include, (E) machining a recess portion through the opening mask using the laser beam such that the right-angled corner of the core pattern is obliquely machined at an angle of 45°.

After (E) forming the upper clad layer, the method may further include, (F) applying a metal mirror on side surfaces of the recess portion.

### BRIEF DESCRIPTION OF THE DRAWINGS

The patent or application file contains at least one drawing executed in color. Copies of this patent or patent application publication with color drawing(s) will be provided by the Office upon request and payment of the necessary fee. These and/or other aspects, features, and advantages will become apparent and more readily appreciated from the following description of exemplary embodiments, taken in conjunction with the accompanying drawings of which:

FIGS. 1 to 3 are cross-sectional views showing a first conventional method of manufacturing a printed circuit board for an optical waveguide using a photo-etching;

FIGS. 4 to 6 are cross-sectional views showing a second conventional method of manufacturing a printed circuit board for an optical waveguide by irradiating the core material using an ultraviolet laser, which changes an index of refraction of a core material;

FIGS. 7 to 10 are cross-sectional views showing a process of manufacturing a printed circuit board for an optical waveguide, according to a preferred embodiment of the present invention;

FIG. 11 is a perspective view showing a laser beam machine and a process of forming a core layer using the same, according to a preferred embodiment of the present invention; and

FIGS. 12 to 14 are plan views showing a process of manufacturing a structure for transmitting an optical signal deflected by the right angle in an optical waveguide, according to a preferred embodiment of the present invention.

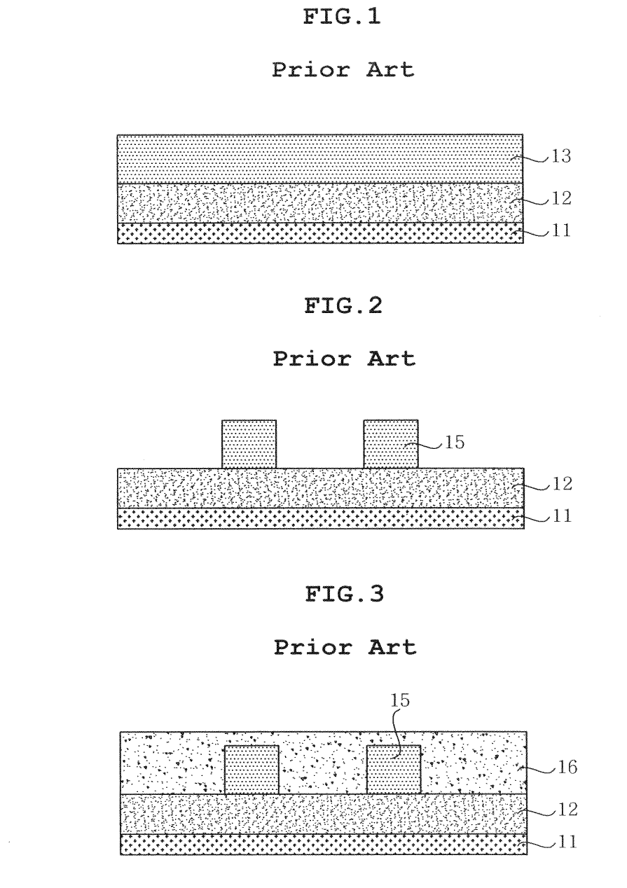

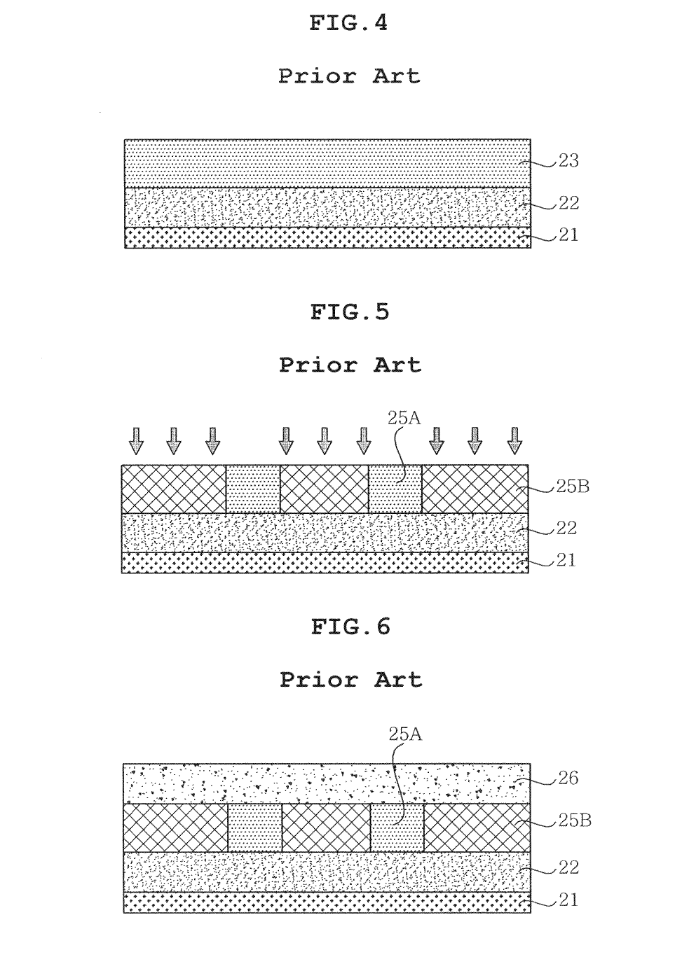

### DETAILED DESCRIPTION OF THE PREFERRED EMBODIMENTS

Various objects, advantages and features of the invention will become apparent from the following description of embodiments with reference to the accompanying drawings. In the designation of reference numerals, it should be noted that the same reference numerals are used throughout the different drawings to designate the same or similar components. Also, in the description of the present invention, when it is considered that the detailed description of a related prior art may obscure the gist of the present invention, such detailed description is omitted.

Hereinafter, an embodiment of the present invention will be described in greater detail with reference to the accompanying drawings.

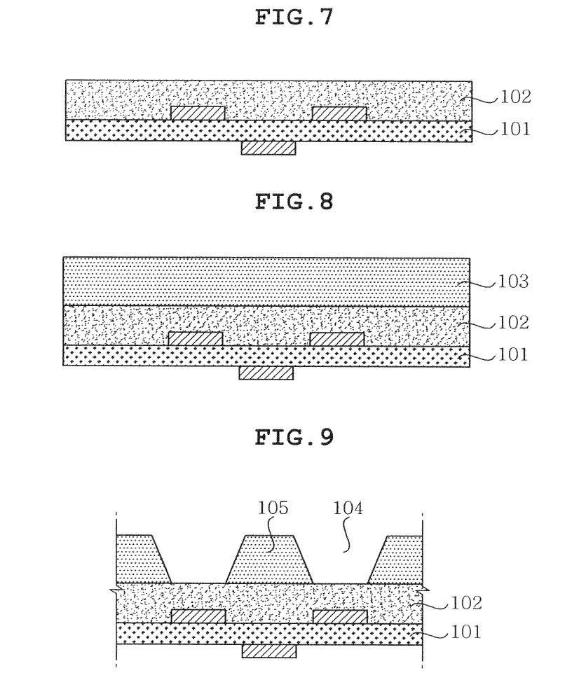

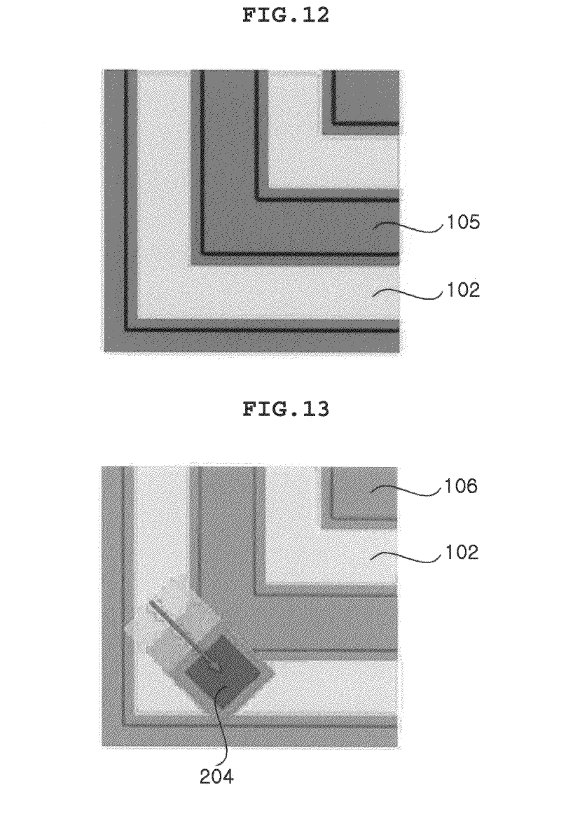

FIGS. 7 to 10 are cross-sectional views showing a process of manufacturing a printed circuit board for an optical waveguide, according to a preferred embodiment of the present invention; FIG. 11 is a perspective view showing a laser beam machine and a process of forming a core layer using the same, according to a preferred embodiment of the present invention; and FIGS. 12 to 14 are plan views showing a process of manufacturing a structure for transmitting an optical signal deflected by the right angle in an optical waveguide, according to a preferred embodiment of the present invention.

Referring to FIGS. 7 to 10, a process of manufacturing a printed circuit board for an optical waveguide according to a preferred embodiment of the present invention is depicted.

As shown in FIG. 7, a lower clad layer 102 is formed on a base substrate 101.

In this regard, the base substrate 101 is intended to serve as a support for the formation of an optical waveguide and to provide electrical wiring for transmitting electrical signals. In the drawing, although the base substrate 101 is illustrated as being an insulating layer having circuit layers formed on both surfaces thereof, it is not particularly limited to this configuration but may also include an insulating layer having a circuit layer formed on a single surface thereof. In this case, the circuit layer functions to transmit electrical signals in conjunction with an optical layer (an optical waveguide) which will be described later.

In addition, although the configuration in which the lower clad layer 102 is formed on the base substrate 101 having the circuit layers is shown in the drawing, another configuration in which the lower clad layer 102 is formed on an insulating layer having a metal layer for forming a circuit and then the metal layer for forming a circuit is patterned to form a circuit layer, should be also construed as falling within the scope of the present invention. Furthermore, other configurations, in which an insulating layer is prepared as the base substrate and then a circuit layer is formed using an additive process, should be also construed as falling within the scope of the present invention.

Also, a material used in the production of the base substrate 101 is not particularly limited to a specific material, and thus a metal layer for forming circuit layer, such as a quartz glass plate, a silicon wafer, a ceramic substrate, a glass epoxy substrate, polyimide film, poly(ethylene terephthalate)(PET) film and a copper foil, and a flexible, rigid or rigid-flexible printed circuit board, may be used.

In order to enhance an adhesive force between the lower clad layer 102 and the base substrate 101, the one surface of the base substrate 101 on which the lower clad layer 102 is formed may be surface-treated using a silane coupling agent or an aluminum chelate agent.

Although the lower clad layer 102 is typically prepared by layering a clad film on the base substrate 101, the technology to prepare the lower clad layer is not tied to this particular way, and thus any of known technologies such as spin coating and screen printing may be employed.

In this embodiment, material of the lower clad layer 102 must have an index of refraction lower than that of the core material 103. For example, the difference between an index of refraction of the core material 103 and an index of refraction of the lower clad layer 102 may be about 0.1%-5%. Furthermore, the lower clad layer 102 may be one having sufficient adhesive force with respect to the core material 103.

Material for making the lower clad layer 012 may include epoxy resin and polyimide resin precursor substances, and more specifically epoxy compound such as 3,4-epoxycyclohexenylmethyl and alicyclic epoxy compound, bisphenol A epoxy resin, bisphenol F epoxy resin, hydrogenated bisphenol A epoxy resin, hydrogenated bisphenol F epoxy resin, naphthalene epoxy resin, aliphatic epoxy resin, fluorinated epoxy resin or a combination thereof.

In addition, in order to enhance adhesive force, a coupling agent such as a silane or a titanate coupling agent, flexibility-imparting agent, antioxidizing agent and antifoaming agent may be used as needed.

Subsequently, as shown in FIG. 8, a core material 103 is layered or applied on the lower clad layer 102.

At this time, the layering and application of the core material 103 may be achieved by applying liquid core material onto the lower clad layer 102 using technology known in the art, such as dispensing, ink jet or printing, and then pre-baking the core material to cure it, but it is not particularly limited to this.

In the present invention, since the core material 103 is etched using a laser, the core material is not particularly limited to a light curing epoxy resin, unlike a conventional process which forms a core layer using the change of index of refraction caused by ultraviolet irradiation.

Thereafter, as shown in FIG. 9, the core material is machined using a laser, thus forming a core layer 105 having a core pattern.

At this time, the core layer 105 is prepared in a manner such that the core material is machined through a polygonal opening mask 204 having linear sides using a laser beam machine such that both side regions of a region corresponding to the core pattern are longitudinally machined to form trenches 104.

When the trench 104 is machined using a laser, in particular a long-wavelength laser, side surfaces of the trench 104 obtain mirror surfaces due to the refraction phenomenon. In other words, upon machining the trench 104, the refraction phenomenon of laser light occurs along the boundaries of the opening mask 204 as shown in FIG. 11, and thus side surfaces having mirror surfaces are obtained.

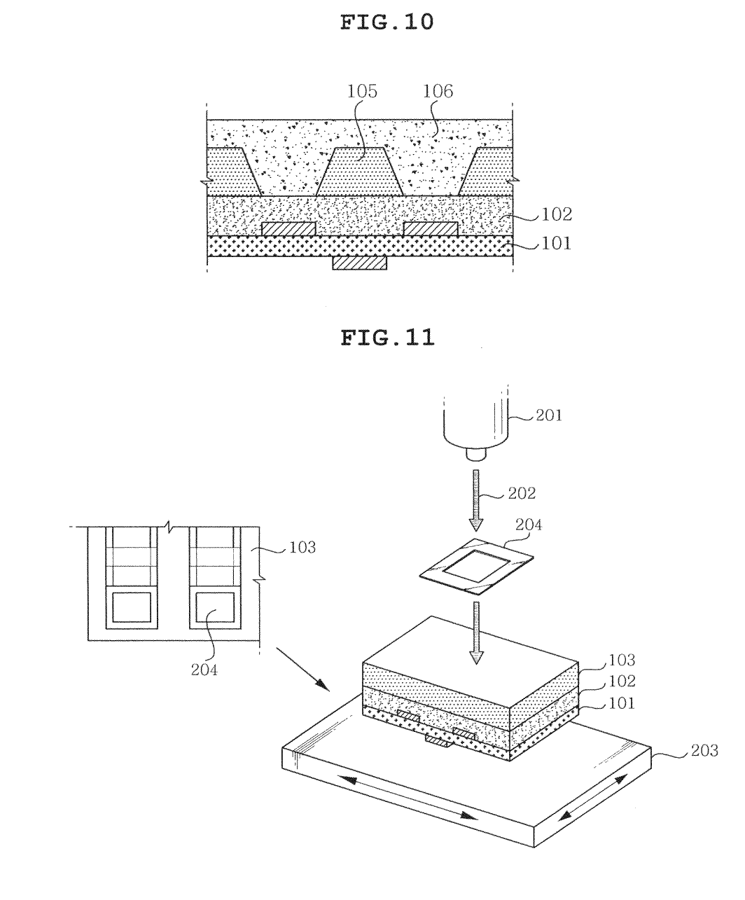

Thereafter, as shown in FIG. 10, an upper clad layer 106 is formed on the core layer 105. An example of the process of forming the upper clad layer 106 may include the same process as the process of forming the lower clad layer 102 which is described above. The material of the upper clad layer 106 may be the same material as that of the lower clad layer 102.

By the above-described manufacturing process, a printed circuit board for an optical waveguide, which is of a hybrid structure having both an electrical layer and an optical layer, is manufactured.

Referring to FIG. 11, a laser beam machine and a process of forming a core layer using the laser beam machine, according to a preferred embodiment of the present invention is depicted.

The laser beam machine according to the present invention comprises a laser beam generator 201, an X-Y movable table 203 and an opening mask 204.

The laser beam generator 201, which is intended to emit a laser beam, may include a laser beam generator for etching core material, for example a CO₂ laser beam generator. The laser beam generator is capable of controlling output power in a pulse or continuous manner, and may control a machining depth depending on a thickness of the core material 103.

In this embodiment, although the laser beam generator 201 is disposed over the X-Y movable table 203 such that a laser beam 202 emitted from the laser beam generator 201 is directed to the X-Y movable table 203, an additional mirror (not shown) for changing the path of laser beam may be also used.

The X-Y movable table 203 is intended to support or move the substrate, and thereon the base substrate 101 including the core material layered or applied thereon is placed. In this embodiment, the trench is longitudinally machined by the movement of the X-Y table 203. However, in the case of machining a narrow trench, the trench may be machined using an optical system disposed between the opening mask 204 and the base substrate 101, and thus the movement of the X-Y movable table 203 is not necessarily required.

The opening mask 204, which is intended to define an area of laser beam projection on the core material 103, is disposed over the X-Y movable table 203 to be aligned with the path of laser beam. In this embodiment, although the opening of the polygonal opening mask 204 has linear sides to machine the trench longitudinally and linearly, it is not limited to linear sides.

A process of forming the core layer 105 using the above-described laser beam machine is briefly described below.

First, the base substrate 101 on which the lower clad layer 102 and the core material 103 are sequentially layered is placed on the X-Y movable table 203.

The base substrate 101 is positioned on the core material using the X-Y movable table 203 such that a portion of a trench region is exposed through the opening of the opening mask 204.

The trench 104 is formed in the core material 103 in an overlapping pulse or continuous manner using the laser beam emitted from the laser beam generator 201. At this point, in order to machine the trench 104 longitudinally, the position of the base substrate 101 is continuously adjusted by means of the X-Y movable table 203 during the machining of the trench 104.

Finally, the X-Y movable table 203 is moved by a predetermined pitch such that a trench region located on the other side of the core pattern is exposed through the opening of the opening mask 204, and then another trench 104 is machined using the laser beam. By machining a plurality of trenches in this way, the core layer 105 is formed.

Referring to FIGS. 12 to 14, a process of forming a structure for transmitting an optical signal in a direction deflected at a right angle, according to a preferred embodiment of the present invention, is described below.

First, as shown in FIG. 12, the lower clad layer 102 and the core material 103 are sequentially formed on the base substrate 101, and then the trench is machined using a laser beam so as to form a core pattern having right-angled corners. At this time, the trench allows the lower clad layer 102 to be exposed to the outside.

Subsequently, as shown in FIG. 13, the upper clad layer 106 is formed on the core layer 105. The opening mask 204 is then oriented such that a corner portion of the core pattern, which has a right angle, is obliquely machined at an angle of 45°, and then a recess portion is machined by irradiation with the laser beam. At this point, the recess portion is formed to have predetermined length and direction by moving the base substrate 101 using the X-Y movable table 203.

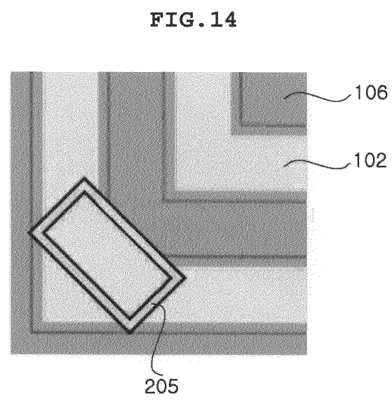

Finally, as shown in FIG. 14, a wall surface of the recess portion, in particular, a wall surface of the recess portion which also defines an inclined surface of the core pattern, is coated with a metal mirror 205. By the application of the metal mirror 205, an optical signal is deflected at a right angle and then transmitted.

As described above, the structure, which is intended to transmit an optical signal deflected at a right angle, can be also simply manufactured through the opening mask using the laser beam machine.

Although the preferred embodiment of the present invention has been disclosed for illustrative purposes, those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

1. A method of manufacturing a printed circuit board for an optical waveguide, comprising:
forming a lower clad layer on a base substrate;
layering or applying a core material on the lower clad layer;
machining a trench in the core material to form a core layer having a core pattern; and
forming an upper clad layer on the lower clad layer and the core layer.

2. The method according to claim 1, wherein the base substrate is a printed circuit board on which a circuit pattern is formed on one or both surfaces of an insulating layer.

3. The method according to claim 1, wherein the machining the trench comprises:
placing the base substrate, on which the lower clad layer and the core material are sequentially formed, on an X-Y movable table which is adjustable in a position;
positioning the X-Y movable table such that an opening of an opening mask positioned over the X-Y movable table is aligned with a region of the core material at which the trench is to be formed; and
machining the trench using a laser beam, thus forming the core layer having the core pattern.

4. The method according to claim 3, wherein the laser beam is a CO₂ laser beam.

5. The method according to claim 3, wherein the opening of the opening mask is a polygon opening having linear sides.

6. The method according to claim 3, wherein in the machining the trench using a laser beam, the trench is machined longitudinally by adjusting a position of the X-Y movable table.

7. The method according to claim 3, wherein in the machining the trench using a laser beam, the core pattern is formed to have a right-angled corner in order to transmit an optical signal in a direction deflected at a right angle.

8. The method according to claim 7, further comprising, after the forming the upper clad layer, machining a recess portion through the opening mask using the laser beam such that the right-angled corner of the core pattern is obliquely machined at an angle of 45°.

9. The method according to claim 8, further comprising, after forming the upper clad layer, applying a metal mirror on side surfaces of the recess portion.
